(19) United States
(12) Patent Application Publication
(10) Pub. No.: US 2025/0239396 A1
(43) Pub. Date: Jul. 24, 2025

(54) INDUCTANCE STRUCTURE

(71) Applicant: TAI-TECH ADVANCED ELECTRONICS CO., LTD., Taoyuan City (TW)

(72) Inventors: Ming-Yen Hsieh, Taoyuan City (TW); Pao-Lin Shen, Taoyuan City (TW); Hsiang-Chung Yang, Taoyuan City (TW); Wei-Hsuan Lo, Taoyuan City (TW)

(21) Appl. No.: 18/416,896

(22) Filed: Jan. 19, 2024

(51) Int. Cl. H01F 27/30; H01F 17/00; H01F 17/04; H01F 27/02; H01F 27/29; H05K 1/18

(52) U.S. Cl. CPC H01F 27/306; H01F 17/04; H01F 27/027; H01F 27/292; H01F 2017/0093; H05K 1/181; H05K 2201/1003

(57) ABSTRACT

The inductance structure includes an iron core having first, second, and third flanges. The first flange has first and second electrodes. The second flange has third and fourth electrodes. The third flange has fifth and sixth electrodes. A first coil has two ends respectively connected to the first and fifth electrodes. A second coil has two ends respectively connected to the second and sixth electrodes. A third coil has two ends respectively connected to the third and fifth electrodes. A fourth coil hasng two ends respectively connected to the fourth electrode of the second flange and the sixth electrode of the third flange. A connection element has two ends respectively connected to the fifth and sixth electrodes. A first common-mode filter is respectively and electrically connected to the first and second electrodes. A second common-mode filter is respectively and electrically connected to the third and fourth electrodes.

### BACKGROUND OF THE INVENTION

### (a) Technical Field of the Invention

The present invention generally relates to inductances, and more particularly to an improved inductance structure for flexible applications.

### (b) Description of the Prior Art

FIG. 1 depicts the equivalent circuit of a conventional capacitor-type module. As shown, the conventional capacitor-type module requires four auto-transformer elements 10 and four common-mode filters 20 to be assembled. This circuit necessitates meticulous assembly, with each component being assembled one by one, making the manufacturing process quite intricate.

### SUMMARY OF THE INVENTION

To obviate the shortcoming of the prior art, the present invention discloses a novel inductance structure, comprising
an iron core having a first flange on a first end, a second flange on a second end opposite to the first end, and a third flange positioned between the first flange and the second flange, where the first flange has a first electrode and a second electrode, the second flange has a third electrode and a fourth electrode, and the third flange has a fifth electrode and a sixth electrode;
a first coil having two ends respectively connected to the first electrode of the first flange and the fifth electrode of the third flange;
a second coil having two ends respectively connected to the second electrode of the first flange and the sixth electrode of the third flange;
a third coil having two ends respectively connected to the third electrode of the second flange and the fifth electrode of the third flange;
a fourth coil having two ends respectively connected to the fourth electrode of the second flange and the sixth electrode of the third flange;
a connection element having two ends respectively connected to the fifth electrode and the sixth electrode of the third flange;
a first common-mode filter respectively and electrically connected to the first electrode and the second electrode of the first flange; and
a second common-mode filter respectively and electrically connected to the third electrode and the fourth electrode of the second flange.

According to the present invention, the present invention can replace a conventional 8-component module, thereby reducing time and cost for production and assembly.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 depicts the equivalent circuit of a conventional capacitor-type module.

FIG. 2 is a perspective diagram showing an inductance structure according to an embodiment of the present invention.

FIG. 3 is a circuit diagram showing the equivalent circuit of the inductance structure of FIG. 2.

FIG. 4 is a circuit diagram showing the equivalent circuit of two inductance structures of FIG. 2 covered by a cover plate.

FIG. 5 is a circuit diagram showing the equivalent circuit of an inductance structure according to another embodiment of the present invention.

FIG. 6 is a schematic diagram showing a scenario where a PCB trace functions as the connection element of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

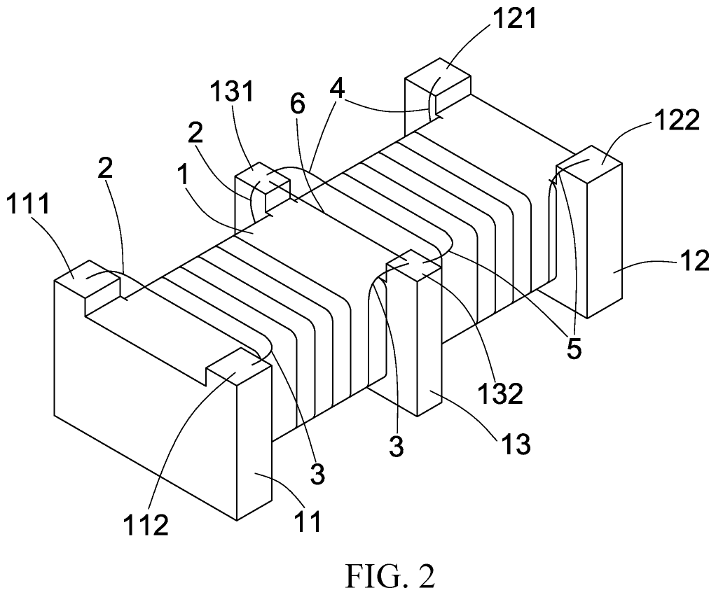

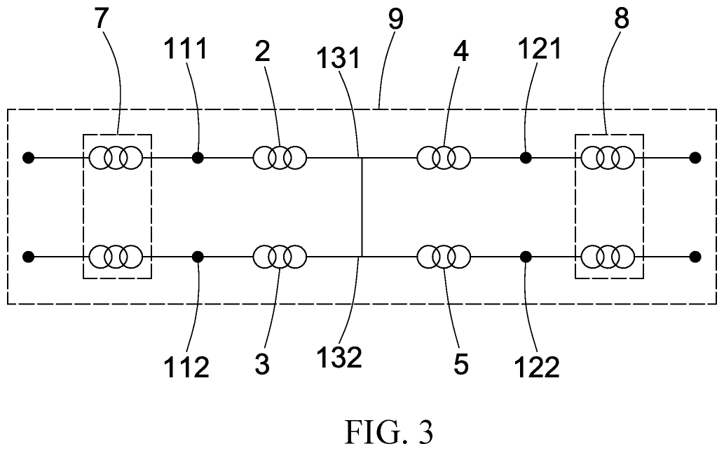

As shown in FIGS. 2 and 3, an inductance structure according to an embodiment of the present invention includes the following components.

An iron core 1 has a first flange 11 on a first end, a second flange 12 on a second end opposite to the first end, and a third flange 13 positioned between the first flange 11 and the second flange 12. The first flange 11 has a first electrode 111 and a second electrode 112, while the second flange 12 has a third electrode 121 and a fourth electrode 122. The third flange 13 has a fifth electrode 131 and a sixth electrode 132. A first coil 2 has its two ends respectively connected to the first electrode 111 of the first flange 11 and the fifth electrode 131 of the third flange 13.

A second coil 3 has its two ends respectively connected to the second electrode 112 of the first flange 11 and the sixth electrode 132 of the third flange 13.

A third coil 4 has its two ends respectively connected to the third electrode 121 of the second flange 12 and the fifth electrode 131 of the third flange 13.

A fourth coil 5 has its two ends respectively connected to the fourth electrode 122 of the second flange 12 and the sixth electrode 132 of the third flange 13.

A connection element 6 has its two ends respectively connected to the fifth electrode 131 and the sixth electrode 132.

A first common-mode filter 7 has two terminals respectively and electrically in connected to the first electrode 111 and the second electrode 112 of the first flange 11.

A second common-mode filter 8 has two terminals respectively and electrically connected to the third electrode 121 and the fourth electrode 122 of the second flange 12.

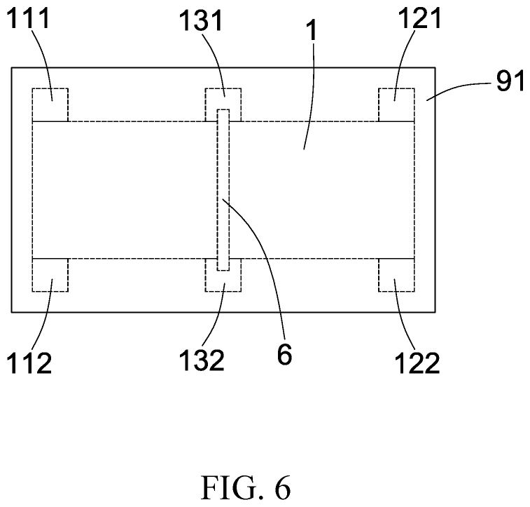

As depicted in FIG. 6, the connection element 6 can be trace on a printed circuit board (PCB) 91, enabling a short circuit between the fifth electrode 131 and the sixth electrode 132.

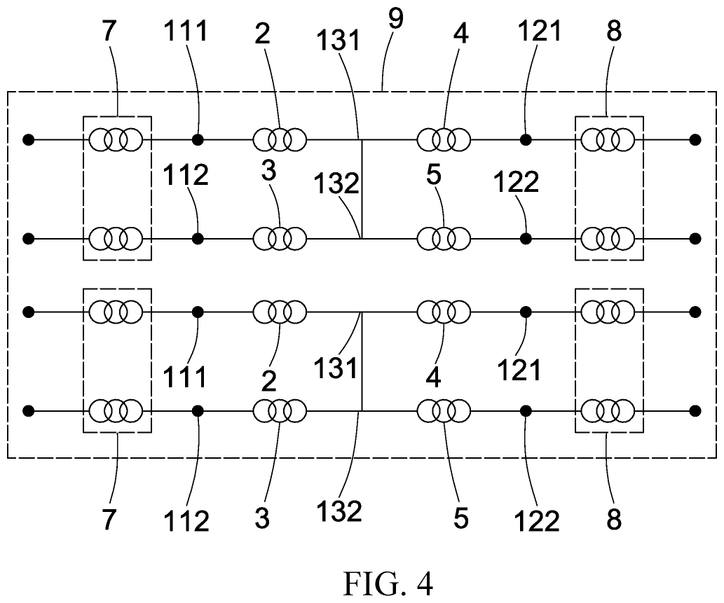

As shown in FIGS. 3 and 4, the inductance structure of the present invention can also include a cover plate 9. The cover plate 9 can be placed over at least one set of iron cores 1, first common-mode filter 7, and second common-mode filter 8, integrating them into a single unit. This makes it easy for external devices to securely attach this unit to a circuit board, providing enhanced convenience in Surface-mount technology (SMT) processes.

The cover plate 9 may also cover only the iron core 1.

Additionally, the cover plate 9 can be made of ceramic material, magnetic material, UV adhesive, or engineering plastic.

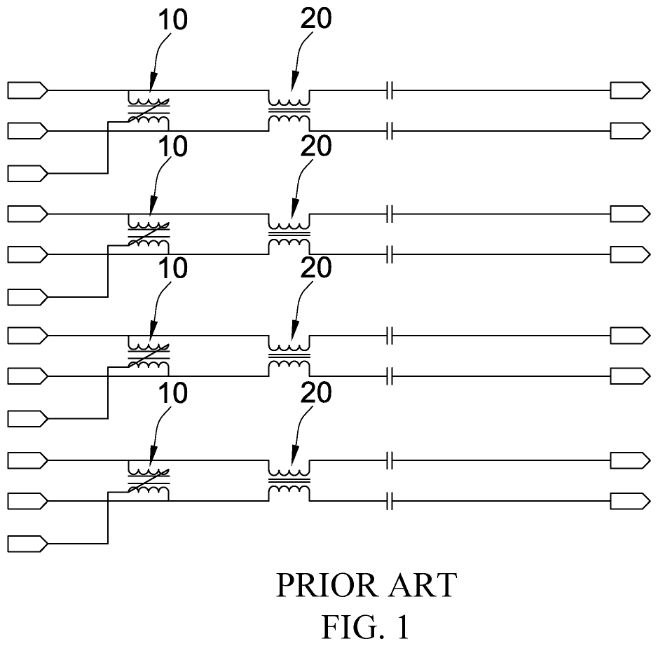

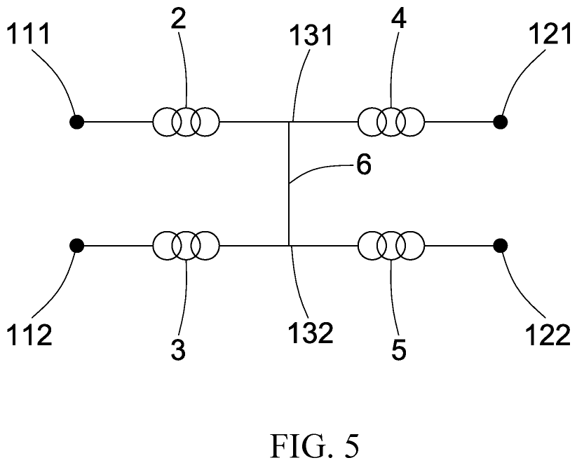

Aa shown in FIGS. 1 and 5, in an alternative embodiment, the inductance structure may omit the first common-mode filter 7 and the second common-mode filter 8, thereby including only the iron core 1, the first coil 2, the second coil 3, the third coil 4, the fourth coil 5, and the connection element 6. In this embodiment, by the connection element 6 bridging the fifth electrode 131 and sixth electrode 132, a single isolation transformer is turned into two auto-transformers, allowing more flexible applications.

According to the present invention, two of the aforementioned inductance structures can replace a conventional 8-component module, thereby reducing time and cost for production and assembly. The cover plate 9 can also turn the inductance structure into an integral entity to facilitate SMT process. Furthermore, the connection element 6 short-circuiting the fifth electrode 131 and the sixth electrode 132 can turn a single isolation transformer into two auto-transformers.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. An inductance structure, comprising:
an iron core having a first flange on a first end, a second flange on a second end opposite to the first end, and a third flange positioned between the first flange and the second flange, where the first flange has a first electrode and a second electrode, the second flange has a third electrode and a fourth electrode, and the third flange has a fifth electrode and a sixth electrode;
a first coil having two ends respectively connected to the first electrode of the first flange and the fifth electrode of the third flange;
a second coil having two ends respectively connected to the second electrode of the first flange and the sixth electrode of the third flange;
a third coil having two ends respectively connected to the third electrode of the second flange and the fifth electrode of the third flange;
a fourth coil having two ends respectively connected to the fourth electrode of the second flange and the sixth electrode of the third flange; and
a connection element having two ends respectively connected to the fifth electrode and the sixth electrode of the third flange.

2. The inductance structure according to claim 1, further comprising a cover plate covering the iron core.

3. The inductance structure according to claim 1, further comprising a first common-mode filter and a second common-mode filter, where the first common-mode filter is respectively and electrically connected to the first electrode and the second electrode of the first flange, and the second common-mode filter is respectively and electrically connected to the third electrode and the fourth electrode of the second flange.

4. The inductance structure according to claim 3, further comprising a cover plate covering the iron core, the first common-mode filter, and the second common-mode filter.

5. The inductance structure according to claim 4, wherein the cover plate is made of ceramic material, magnetic material, UV adhesive, or engineering plastic.

6. The inductance structure according to claim 1, wherein the connection element is a trace on a printed circuit board (PCB).
